(19) United States
(12) Patent Application Publication
(10) Pub. No.: US 2011/0088936 A1
(43) Pub. Date: Apr. 21, 2011

(54) METHOD FOR MANUFACTURING AN ELECTRONIC ASSEMBLY

(76) Inventors: Ulrich Schaaf, Kaiserbach (DE); Andreas Kugler, Alfdorf (DE)

(21) Appl. No.: 12/736,045

(22) PCT Filed: Mar. 13, 2009
(86) PCT No.: PCT/EP2009/052953

§ 371 Date: Nov. 29, 2010

(30) Foreign Application Priority Data
Mar. 27, 2008 (DE) 10 2008 000 842.7

(51) Int. Cl. H05K 1/18; H05K 3/30

(52) U.S. Cl. 174/260; 29/832

(57) ABSTRACT

A method for manufacturing an electronic assembly (27), including a circuit board (29) having at least one electronic component (9, 13), in which at least one electronic component (9) having contacting points (11) is initially fastened on a conductive film (1), the active side of the at least one electronic component (9) facing in the direction of the conductive film (1) and the contacting points (11) being positioned at contacting positions on the active side of the electronic component (9). The conductive film (1) having the at least one electronic component (9, 13) fastened thereto is then laminated onto a circuit board carrier (17), the at least one electronic component (9, 13) facing in the direction of the circuit board carrier (17). Finally, a printed conductor structure (25) is implemented by structuring the conductive film (1). Furthermore, the present invention relates to an electronic assembly.

### BACKGROUND OF THE INVENTION

1. Description of Related Art

The present invention relates to a method for manufacturing an electronic assembly, including a circuit board having at least one electronic component, and an electronic assembly.

2. Description of Related Art

In order to be able to encapsulate electronic components, which are used in electronic assemblies on a circuit board, and increase the surface use on the electronic circuit board, receiving the electronic components in the circuit board is known. Protection of the electronic components is possible in this way. For example, milling receptacles into a circuit board substrate, in which the electronic components are laid, is known from U.S. Pat. No. 6,512,182. After the electronic components are inlaid, the receptacles are filled, subsequently smoothed, and laminated over. A smooth surface of the electronic assembly may be achieved by the embedding of the electronic components.

The disadvantage of this assembly is that receptacles are initially milled into the circuit board substrate, into which the electronic components are inserted. Exact positioning of the electronic components is only possible with great difficulty in this way.

A method for manufacturing an electrical circuit is known from published German patent application DE-A 10 2005 003 125, the circuit having electrical components, which are mechanically connected to one another by a grouting compound. At least one layer of printed conductors, which electrically connects the components to one another, is provided on at least one side of the grouting compound. To manufacture the circuit, the components are applied to a carrier film and subsequently embedded using a grouting compound. The carrier film is subsequently removed and one or more layers of printed conductors, which electrically connect the components to one another, are applied on the side on which the components were connected to the carrier film.

The disadvantage of this method is that the carrier film must be removed without residue to achieve a functional connection of the electrical circuit.

An additional disadvantage of the method known from the related art is that the equipped surface on the circuit board is limited because of the circuit board structure. In addition, the terminals are sometimes relatively long, which is disadvantageous for applications in the range of higher clock frequencies.

### SUMMARY OF THE INVENTION

The method according to the present invention for manufacturing an electronic assembly, including a circuit board having at least one electronic component, includes the following steps:

(a) fastening at least one electronic component having contacting points on a conductive film, the active side of the at least one electronic component facing in the direction of the conductive film and the contacting points being positioned at contacting positions on the active side of the electronic component,
(b) laminating the conductive film having the at least one electronic component fastened thereon on a circuit board carrier, the at least one electronic component facing in the direction of the circuit board carrier,
(c) implementing a printed conductor structure by structuring the conductive film.

In the sense of the present invention, the contacting points are small protrusions made of a conductive material, which are attached at the contacting positions of the electronic component. The height of the protrusions corresponds to the distance which the electronic component is to assume from the electrically conductive film. Suitable contacting points are, for example, solder bumps or stud bumps. The contacting points are used at the same time for bonding the electronic component to the electrically conductive film. Short terminals which are advantageous in particular for applications in the range of higher clock frequencies are implemented in this way. An additional advantage is that in this way the electronic component is already bonded during the installation, making it possible to reduce the number of processing steps. An additional advantage of the bonding of the electronic components to the contacting points is that no space is required to connect upper terminals of the electronic component to the electrically conductive film. In this way, denser equipping may be performed, resulting in increased surface use.

An additional advantage is that high-risk mixed techniques, such as soldering, gluing, and wire bonding, are avoided in the manufacturing.

An additional advantage of the method according to the present invention is that the electronic components may be exactly positioned by the fastening on the conductive film. During subsequent lamination of the conductive film having the at least one electronic component fastened thereon on a circuit board carrier, with the at least one electronic component facing in the direction of the circuit board carrier, the at least one electronic component is enclosed by the circuit carrier. The component is thereby completely encapsulated. High reliability of the electronic assembly is achieved by the complete encapsulation of sensitive components.

Furthermore, a planar starting structure is achieved, whereby reproducible high-frequency transitions are produced.

As a result of the structuring of the conductive film after the lamination on the circuit board carrier, the required printed conductors are manufactured in a simple way. Rapid and cost-effective manufacturing of the electronic assembly is thus possible.

In a first specific embodiment of the method according to the present invention, the conductive film has an insulating layer. The at least one component is fastened on the insulating layer, the contacting points breaking through the insulating layer and contacting the component with the conductive film. The insulating layer acts as a dielectric material and is used so that the entire active side of the electronic component does not rest on the conductive film.

In an alternative, particularly preferred specific embodiment, adhesive is applied to the conductive film to fasten the at least one electronic component. The adhesive acts as a dielectric material between the conductive film and the at least one electronic component. The contacting points also contact the component with the conductive film in this specific embodiment. The advantage of the specific embodiment in which the adhesive is applied to the conductive film is that coating of the conductive film is not necessary. This has cost advantages in relation to the coated film, because the application of adhesive to a film is more cost-effective than the coating of a film.

In addition to the components having contacting points, it is furthermore possible that in one specific embodiment, at least one additional electronic component without contacting points is also fastened on an insulating layer or an adhesive layer on the conductive film.

In a preferred specific embodiment, the at least one electronic component and optionally the at least one additional electronic component are enclosed by a polymer compound after the fastening on the conductive film. The enclosure of the at least one electronic component using the polymer compound results in additional protection of the component. The danger of damage is thus also significantly reduced in the case of sensitive components.

The polymer compound, via which the at least one electronic component and optionally the at least one additional electronic component are enclosed, is a low-pressure molding compound, such as an epoxy low-pressure molding compound. The low-pressure molding compound is applied by a transfer molding method, for example. Additional placeholders, for example, for thicker dielectric materials, may be kept free in the polymer compound. These may also be extrusion coated as inlay parts during the extrusion coating of the at least one electronic component, however.

The at least one electronic component and optionally the at least one additional electronic component are preferably fastened by gluing. For this purpose, it is preferable in the first specific embodiment that the conductive carrier film has an adhesive layer. The adhesive layer preferably forms the insulating layer at the same time. The insulating layer is a self-adhesive conductive film, for example. The gluing may be performed by heating and compression processes. This is also a hot glue process, for example. In the second specific embodiment, the at least one component and optionally the at least one additional component are glued by applying adhesive to the electrically conductive film. The adhesive may be applied by any desired method known to those skilled in the art. It is thus possible, for example, to apply the adhesive to the electrically conductive film in the form of adhesive dots. Furthermore, it is also possible to paint the electrically conductive film using an adhesive layer, for example. The adhesive is preferably applied in the form of adhesive dots at the positions at which electronic components are attached, however.

The conductive film which is used is a copper film, for example, such as is also known as RCC material from circuit board technology. Other suitable conductive films are LCP films or PI films, for example. In addition to copper, aluminum is also suitable as the metal, for example.

In a preferred specific embodiment, before applying the at least one electronic component to the conductive film in step (a), alignment marks are introduced into the conductive film. The alignment marks are holes or pocket holes having a desired cross section, for example. They may be introduced into the conductive film by etching, punching, or drilling, for example. The alignment marks are applied on the side of the conductive film which is diametrically opposite to the at least one electronic component. The precise position of the at least one electronic component and optionally the at least one additional electronic component may be determined by the alignment marks even after the enclosure of the at least one electronic component using the polymer compound or after the lamination of the conductive film on the circuit board carrier. This is necessary, on the one hand, for the implementation of the printed conductor structure; on the other hand, it is required for the contacting of the at least one additional component, if such a component is applied without contacting points. Alternatively, components, via which the conductive film is equipped, are also suitable as alignment marks. The conductive film is preferably drilled out or X-rayed at the positions at which the components are positioned in order to recognize the components. In addition, the alignment marks may also have any other form known to those skilled in the art, of course.

If additional electronic components which do not have contacting points are to be attached, holes are preferably introduced at the positions at which the at least one additional electronic component is to be electrically contacted with the conductive carrier film. The holes are metal plated, for example, to contact the conductive film with the at least one additional electronic component. The holes are introduced by laser drilling, for example. The positions at which the holes are introduced are determined on the basis of the alignment marks.

The metal plating of the holes to achieve a contact of the at least one additional electronic component with the conductive carrier film is performed according to methods known to those skilled in the art. The metal plating may be performed by electroless metal deposition, for example. Electroless metal deposition is a typical method which is used in circuit board manufacturing. The metal plating of the holes is preferably performed using copper.

Additional printed conductors may be applied, for example, in that additional layers which contain printed conductor structures are applied to the conductive film which is structured in step (c). For this purpose, firstly a dielectric material is preferably applied, by which the printed conductors implemented in step (c) are covered. The printed conductors are simultaneously insulated in this way, so that no undesired electrical contact with the printed conductors of the subsequently applied layer occurs. Additional printed conductors are then applied to the dielectric material according to the method known to those skilled in the art. The additional layers, which contain printed conductors, may alternatively also be manufactured by applying additional conductive films to the first layer and subsequently structuring the film to implement printed conductors. The films preferably include an adhesive insulating layer, via which they are applied to the printed conductors.

The contacting between two layers having printed conductors is performed, for example, by introducing holes and subsequently metal plating the holes. Alternatively, it is also possible not to apply dielectric material at the positions at which the printed conductors of the second layer are to contact the printed conductors of the first layer.

In order to dissipate heat arising during operation of the electronic assembly, it is preferable that the at least one electronic component is contacted with a heat sink, on the side facing away from the conductive film, after the lamination of the conductive film on the circuit board carrier in step (b), so that the heat sink is also integrated in the circuit board after the lamination on the circuit board carrier. The heat sink may be any heat sink known to those skilled in the art. It is thus possible that the heat sink is a metal core, for example. During operation, the electronic component dissipates heat to the metal core, via which it may be discharged to the outside.

Cost-effective wiring and encapsulation may be achieved by the method according to the present invention by the use of processes on many modules simultaneously. An additional advantage is that the electronic assembly may be processed further as a standard component.

Furthermore, the present invention relates to an electronic assembly, including at least one electronic component which is connected to a printed conductor structure on a circuit board. The at least one electronic component is embedded in a circuit board carrier and the printed conductor structure is positioned on the surface of the circuit board. The component is contacted with the printed conductor structure through contacting points attached to the component. In addition to the above-mentioned cost-effective encapsulation and thus high reliability, the costly substrate and package technology, as is currently used in the related art, is replaced or reduced to a small component. In addition, it is possible in the case of the electronic assembly according to the present invention to concentrate a complete high-frequency circuit on one module, including antennas. The electronic assembly manufactured according to the present invention may be processed further as a standard component.

The contacting points are preferably solder bumps or stud bumps. Furthermore, bumps produced by electroplating from various materials, such as copper or gold, are suitable. As a result of automated application of the solder bumps or stud bumps, it is possible that they each have a uniform height. A uniform distance of the electronic component from the conductive film may be achieved in this way.

In a preferred specific embodiment, the printed conductor structure is implemented in multiple layers. Increased surface use on an electronic circuit carrier is possible in this way.

As a result of the additional layers, the electronic assembly may be equipped and contacted using components in the smallest possible space.

In order to be able to dissipate heat well, which arises during operation of the electronic assembly, it is preferable for a heat sink to be contained in the circuit board. For example, a metal core, on which the at least one electronic component is metallically fastened, is suitable as the heat sink.

In addition to the at least one electronic component, it is also possible that the electronic assembly contains one or more mechanical components.

The electronic components used in the method according to the present invention or in the electronic assembly according to the present invention are all electronic components known to those skilled in the art, as used in circuit board technology and microelectronics. All components as used in circuit board technology also come into consideration as the mechanical components.

### BRIEF DESCRIPTION OF THE SEVERAL VIEWS OF DRAWINGS

Exemplary embodiments of the present invention are shown in the drawings and are explained in greater detail in the following description.

FIGS. 1 through 5 show multiple steps of the manufacture of a device according to the present invention in a first specific embodiment.

FIGS. 6 through 10 show multiple steps of the manufacture of a device according to the present invention in a second specific embodiment.

### DETAILED DESCRIPTION OF THE INVENTION

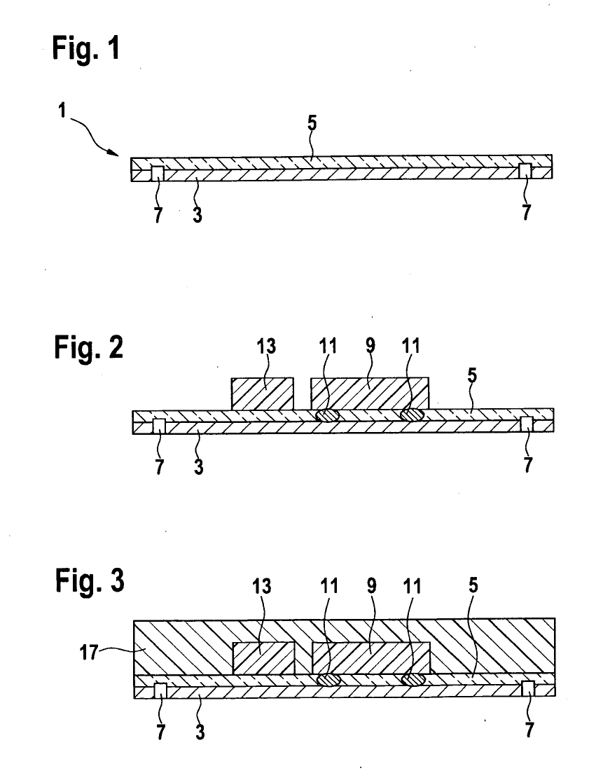

A conductive film 1, which includes a conductive layer 3 and an insulating layer 5, is shown in FIG. 1. Insulating layer 5 is preferably an adhesive layer or a thermoplastic, on which electronic components may be applied. Alignment marks 7 are introduced on the side of conductive film 1 on which conductive layer 3 is located. Alignment marks 7 may be introduced into conductive film 1, for example, by etching, punching, or drilling, such as laser drilling. Furthermore, it is possible that alignment marks 7 are also components which are connected to conductive film 1, which are drilled out or detected by X-ray microscopy. Any other form of alignment marks known to those skilled in the art is also possible.

Conductive layer 3 is preferably a metal layer. Copper is particularly preferred as the metal.

In a second step, electronic components 9 are applied to insulating layer 5. This is shown in FIG. 2. The electronic component is fastened with its active side facing toward conductive film 1. Contact points 11 are attached to electronic component 9 at the positions at which electronic component 9 is contacted with conductive film 1. Contact points 11 are preferably bumps made of an electrically conductive material. Contact points 11 are preferably solder bumps or stud bumps. In addition to electrical component 9 having contact points 11, it is also possible to apply additional electronic components 13, which do not have contact points 11, on insulating layer 5 of conductive film 1. In addition to electronic components 9, 13, it is also possible that mechanical components are applied to insulating layer 5 of conductive film 1. Electronic components 9, 13 or mechanical components which are applied to insulating layer 5 of conductive film 1 are typical components as used in circuit board construction. These include, for example, chips, processors, high-frequency components, SMD components, antenna modules, heat sinks, MEMS, or MOEMS.

Electronic components 9, additional electronic components 13, or the mechanical components are preferably applied by gluing onto insulating layer 5. For this purpose, electronic components 9, 13 are placed on insulating layer 5 of conductive film 1 in the way in which electronic components 9, 13 are to be positioned later in the electrical circuit. For example, heat sinks may be applied to individual or all electronic components 9, 13, to ensure increased heat dissipation during the operation of electronic components 9, 13. The heat sinks which may optionally be provided are placed for this purpose on the side of electronic components 9, 13 facing away from conductive film 1.

In order to achieve encapsulation of sensitive electronic components 9, 13, it is possible to enclose them using a polymer compound 15. This is shown in FIG. 5, for example. Polymer compound 15 is, for example, an epoxy low-pressure molding compound. If necessary, placeholders for thicker dielectric materials, for example, which are used for antennas or heat sinks, for example, may be extrusion coated in polymer compound 15. The enveloping using polymer compound 15 is performed, for example, via a transfer molding method. For example, the placeholders may be shaped as depressions or troughs. In addition to the transfer molding method, however, any other method known to those skilled in the art is also usable, via which electronic components 9, 13 may be embedded using polymer compound 15. In addition, the embedding using polymer compound 15 has the advantage that height compensation is possible in the case of components 9, 13 having a differing thickness. This is advantageous for the following lamination process. Components may additionally be pre-encapsulated on removable film and installed on conductive film 1 after the removal of the film.

After electronic component 9 is applied to conductive film 1 or, if electronic components 9, 13 are to be enclosed by the polymer compound, after the enclosure of electronic components 9, 13 using polymer compound 15, conductive film 1 is cut to the size of the circuit board blank.

After cutting to size, conductive film 1 having electronic components 9, 13 attached thereto and optionally additional mechanical components, which are not shown here, are laminated on a circuit board carrier 17. This is shown in FIG. 3. In the embodiment variant shown here, conductive film 1 having electronic components 9, 13 has been laminated on circuit board carrier 17, without electronic components 9, 13 having been enclosed by polymer compound 15. According to the present invention, however, the specific embodiment shown in FIG. 5, in which electronic components 9, 13 are enclosed by polymer compound 15, is also laminated on circuit board carrier 17. The lamination is performed according to the methods known to those skilled in the art. Circuit board carrier 17 is laminated according to the present invention onto conductive film 1 in such a way that electronic components 9, 13 or electronic components 9, 13 which are enclosed by polymer compound 15 are enclosed by circuit board carrier 17. For this purpose, circuit board carrier 17 is laminated onto conductive film 1 on the side on which electronic components 9 are also attached.

In general, for this purpose in the case of components 9, 13 whose component thickness is greater than 0.1 mm, a glass-fiber-reinforced, cured circuit board material, which is pre-drilled at the positions of components 9, 13, is initially applied to the film. A prepreg and optionally an additional cured circuit board material are laid thereon. This stack is compressed in a lamination process. The cured circuit board material is typically a glass-fiber-reinforced epoxy resin. However, any other suitable material known to those skilled in the art is usable. In general, an epoxy resin is also used as the prepreg. However, it is not yet completely cured. By applying pressure and an elevated temperature, the prepreg cures completely, whereby it bonds to the cured circuit board material. The composite made of prepreg and cured circuit board material forms circuit board carrier 17.

After the lamination of conductive film 1 having electronic components 9, 13 or having electronic components 9, 13 optionally enclosed by polymer compound 15 on circuit board carrier 17, holes 19 are introduced into conductive film 1, including conductive layer 3 and insulating layer 5, at the terminal positions of additional electronic components 13, which do not have contact points 11. The correct positioning of holes 19 may be ascertained by initially introduced alignment marks 7. It is thus possible to create holes 19 precisely at the positions at which the electrical terminals of additional electronic component 13 are located. Electronic components 9, which have contact points 11, are contacted using their contact points 11 on conductive layer 3 of conductive film 1.

Cooling channels 21, as shown in FIG. 5, are typically drilled in circuit board carrier 17 simultaneously with the introduction of holes 19 for contacting additional electronic components 13 with conductive layer 3 or directly following this. A laser drilling method is used for this purpose, for example. If holes 19 are also created by a laser drilling method, a second laser is preferably used for cooling channels 21. However, all holes 19 and cooling channels 21 may also be drilled using the same laser.

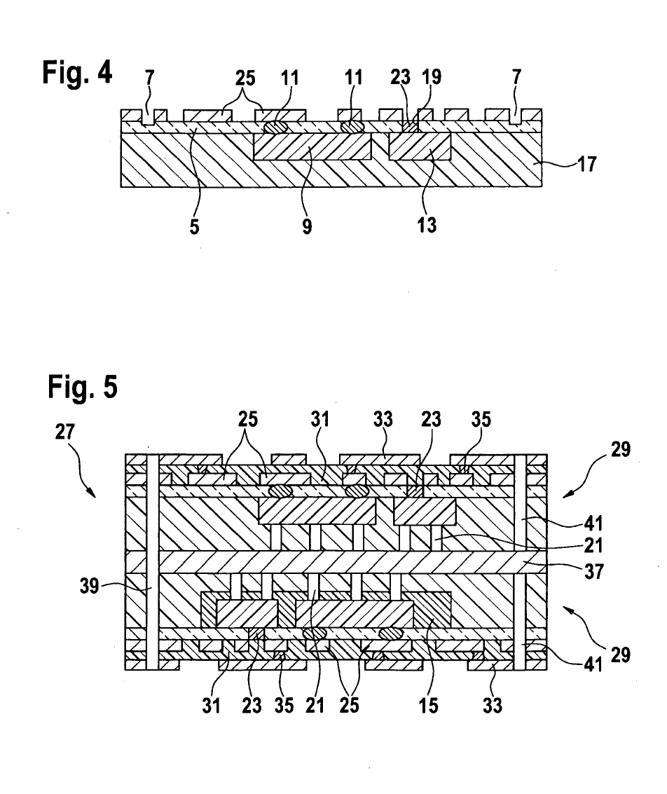

Additional electronic components 13 are electrically contacted with conductive layer 3 by metal plating. This is shown in FIG. 4. Metal 23 is deposited in holes 19 by methods known to those skilled in the art, for example, by electroless metal deposition, for the metal plating. This metal connects the terminals of additional electronic components 13 to conductive layer 3. An electronic contact was produced. Metal 23, which is used for the metal plating, is typically copper. A starting metal plating made of palladium is generally first deposited without electricity for the metal plating. Copper electroplating is performed thereafter. Metal 23 may assume the form of a sleeve or completely fill holes 19.

After the introduction of holes 19 for the contacting of additional electronic components 13 into conductive film 1 and the metal plating of holes 19, conductive layer 3 is structured as shown in FIG. 4. The structuring is performed by any desired method known to those skilled in the art. Suitable methods are, for example, etching methods, photoresist methods, laser drilling methods, or laser ablation methods.

Printed conductor structures 25, which are required for the circuit board, are created by the structuring of the conductive layer.

A level surface is achieved by the embedding of electronic components 9, 13 in circuit board carrier 17. Simple processing of the surface is thus possible. Of course, however, it is also possible to first work printed conductor structure 25 out of conductive film 1 and introduce the holes into conductive film 1 and metal plate them thereafter.

An electronic assembly 27 is shown in FIG. 5. Electronic assembly 27 includes two circuit boards 29. A dielectric material 31 is applied to printed circuit conductor 25, in order to apply an additional printed conductor structure 33. For example, epoxy resins or FR4 materials, which are known from circuit board technology, are suitable as dielectric material 31. Dielectric material 31 is applied using typical methods known to those skilled in the art. It is thus possible, for example, to apply dielectric material 31 by squeegeeing, painting, printing, lamination, curtain coating, film coating, spray coating, or similar methods.

An additional printed conductor structure 33 is applied to dielectric material 31. For this purpose, it is possible to first apply a conductive layer over the entire area, which is subsequently structured.

It is preferably also possible to apply an additional conductive film to first printed conductor structure 25 and to structure printed conductor structure 33 from the conductive layer of the second conductive film. This is preferably performed according to the same method as the structuring of conductive layer 3 to form printed conductor structure 25. After the production of printed conductor structure 33, holes 35 via which printed conductor structure 25 is contacted with additional printed conductor structure 33 using metal plating may be introduced into dielectric material 31.

For producing multiple conductive layers, which are structured to form printed conductors, first dielectric material 31 and subsequently a conductive film are particularly preferably laminated on. After dielectric material 31 and the conductive film are laminated on, holes are first introduced, which are subsequently metal plated to electrically connect the conductive film to layers lying underneath. Additional printed conductor structure 33 is subsequently worked out of the conductive film.

In order to dissipate heat from electronic components 9, 13, it is possible to introduce cooling channels 21 into circuit board carrier 17 on the side of electronic components 9, 13 facing away from printed conductor structures 25, 33. Cooling channels 21 may be connected to a heat sink 37. In the specific embodiment shown in FIG. 5, heat sink 37 is a metal core. Heat is dissipated from electronic components 9, 13 via heat sink 37 and cooling channels 21. Cooling channels 21 are generally attached to heat sink 37 via a rear side metal plating or alternative attachments, in which the inner walls of cooling channels 21 are provided with a metal layer. However, it is also possible to completely fill cooling channels 21 using a metal.

Furthermore, it is also possible to provide cooling elements between heat sink 37, which is implemented as a metal core, and electronic component 9, 13. It is also possible to design the metal core in such a way that it directly contacts electronic components 9, 13.

Circuit boards 29 are preferably also connected using a lamination process, as is typical in circuit board manufacturing processes.

Using a hole 39, which leads through both circuit boards 29, printed conductor structure 25 of one circuit board 29 may be connected to printed conductor structure 33 of second circuit board 29. The electrical contact is achieved, for example, by a metal plating of the wall of hole 39. Using a hole 41, which ends at heat sink 37, which is implemented as a metal core, printed conductor structure 25, 33 may be electrically contacted with the metal core. A ground contact may be implemented in this way, for example. The electrical contact is also preferably produced by metal plating in hole 41. The metal plating of holes 39, 41 is created, for example, by electroless metal deposition or electroplating. However, it is alternatively also possible to lead a wire through holes 39, 41.

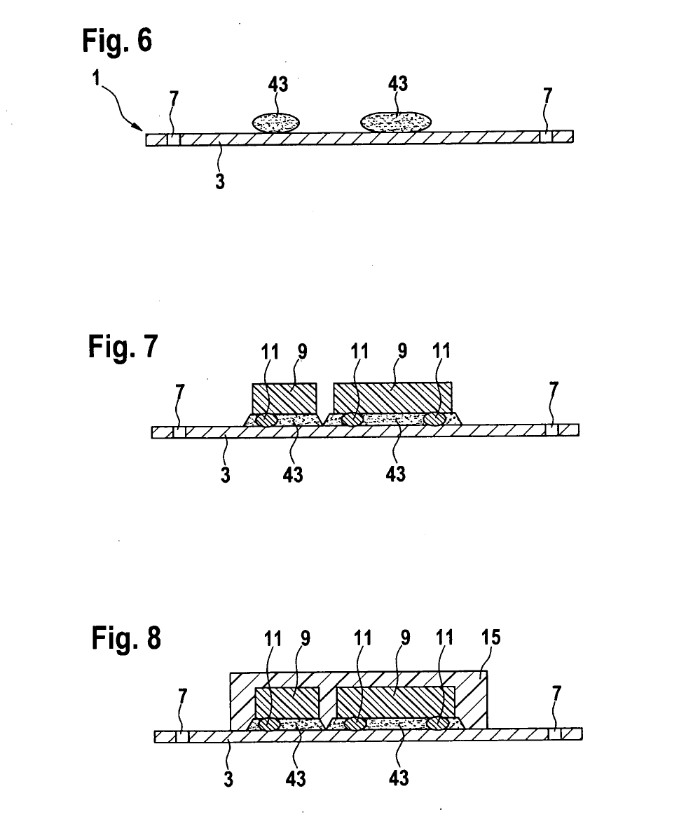

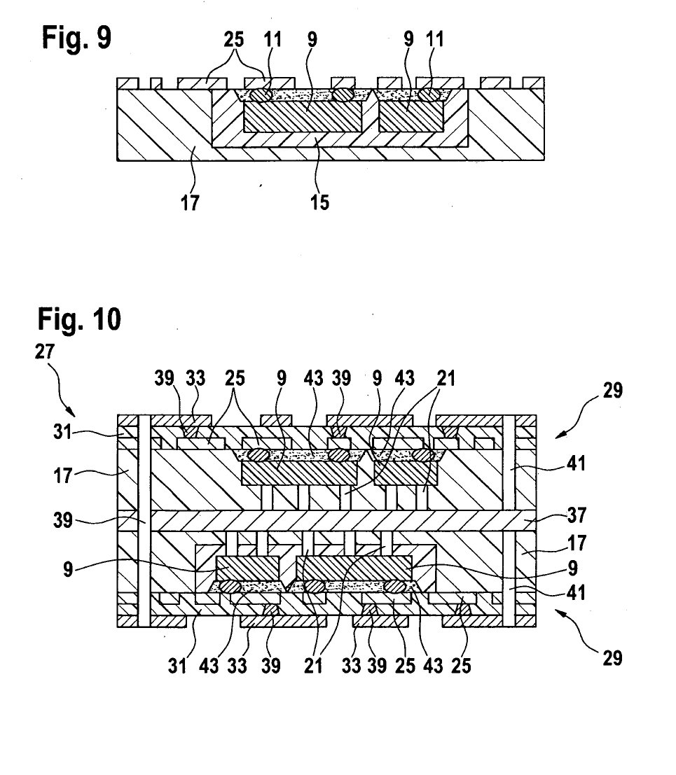

An alternative method for manufacturing an electronic assembly 27 is shown in FIGS. 6 through 10. The method shown in FIGS. 6 through 10 differs from the method shown in FIGS. 1 through 5 in that conductive film 1 only has one conductive layer 3 and no insulating layer 5. Alignment marks 7 are introduced into conductive film 1. Adhesive 43 is applied to conductive film 1 for fastening electronic components 9. Adhesive 43 may be applied flatly or preferably in the form of adhesive dots, as shown in FIG. 6.

Electronic components 9, which are provided with contact points 11, are attached on adhesive dots 43. The distance of electronic components 9 to conductive film 1 is established by contact points 11. Adhesive 43 fills up the intermediate space between electronic component 9 and conductive film 1 and forms a dielectric material, so that the active side of electronic components 9 does not rest directly on conductive film 1. This is shown in FIG. 7.

In order to achieve encapsulation of sensitive electronic components 9, it is possible to enclose them using polymer compound 15. This is shown in FIG. 8. Polymer compound 15 is an epoxy low-pressure molding compound, for example. If necessary, for example, placeholders for thicker dielectric materials, which are used for antennas or heat sinks, for example, may be extrusion coated in polymer compound 15. The enveloping using polymer compound 15 is performed using a transfer molding method, for example. The placeholders may be shaped as depressions or troughs, for example. In addition to the transfer molding method, however, any other method known to those skilled in the art via which electronic components 9 may be embedded using polymer compound 15 is also usable. In addition, the embedding using polymer compound 15 has the advantage that a height compensation is possible in the case of components 9 having a varying thickness. This is advantageous for the following lamination process. Components may additionally be pre-encapsulated on removable films and installed on film 1 using adhesive 43 after the removal of the film.

As in the specific embodiment shown in FIGS. 1 through 5, printed conductor structure 25 is formed from conductive film 1 after electronic components 9 are glued on and optionally the encapsulation using polymer compound 15. If all electronic components 9, as shown in FIGS. 6 through 10, are equipped using contact points 11 and are connected via contact points 11 to conductive film 1, it is not necessary to form holes 19, which are subsequently metal plated to produce an electrical contact, for electrical contacting. However, if additional electronic components 13 which do not have contact points 11 are glued on using adhesive 43, holes 19 are introduced through conductive film 1 and adhesive 43, which are subsequently metal plated to contact additional electronic component 9, 13 with conductive film 1. In this case, conductive film 1 is only structured to form printed conductor structure 25 after the introduction of holes 19.

Prior to structuring of conductive film 1 to form printed conductor structure 25, circuit board carrier 17 is also initially laminated onto conductive film 1 in the specific embodiment shown in FIGS. 6 through 10, as described above.

FIG. 10 shows an electronic assembly 27, in which two circuit boards 29 are connected to one another. The construction corresponds to the construction of electronic assembly 27 shown in FIG. 5. Electronic assembly 27 shown in FIG. 10 differs from the specific embodiment shown in FIG. 5 in that a continuous insulating layer 5 is not implemented between circuit board carrier 17 and printed conductor structure 25. Adhesive 43, via which electronic components 9 are glued onto printed conductor structure 25, is used as the dielectric material between printed conductor structure 25 and electronic component 9. In areas in which no electronic component 9 is located, printed conductor structure 25 is applied directly to circuit board carrier 17.

1-13. (canceled)

14. A method for manufacturing an electronic assembly which includes a circuit board having at least one electronic component, said method comprising:
(a) fastening at least one electronic component having contacting points on a conductive film, an active side of the at least one electronic component facing in the direction of the conductive film and the contacting points being positioned at contacting positions on the active side of the electronic component,
(b) laminating the conductive film having the at least one electronic component fastened thereto onto a circuit board carrier, the at least one electronic component facing in the direction of the circuit board carrier, and
(c) implementing a printed conductor structure by structuring the conductive film.

15. The method as recited in claim 14, wherein the conductive film has an insulating layer and the at least one component is fastened on the insulating layer, the contacting points breaking through the insulating layer and contacting the component with the conductive film.

16. The method as recited in claim 14, wherein adhesive is applied to the conductive film to fasten the at least one electronic component, the adhesive acting as a dielectric material between the conductive film and the at least one electronic component and the contacting points contacting the component with the conductive film.

17. The method as recited in claim 14, wherein at least one additional electronic component without contacting points is fastened on an insulating layer or an adhesive layer on the conductive film.

18. The method as recited in claim 15, wherein at least one additional electronic component without contacting points is fastened on an insulating layer or an adhesive layer on the conductive film.

19. The method as recited in claim 16, wherein at least one additional electronic component without contacting points is fastened on an insulating layer or an adhesive layer on the conductive film.

20. The method as recited in claim 14, wherein the at least one electronic component is enclosed by a polymer compound after the fastening on the conductive film.

21. The method as recited in claim 15, wherein the at least one electronic component is enclosed by a polymer compound after the fastening on the conductive film.

22. The method as recited in claim 16, wherein the at least one electronic component is enclosed by a polymer compound after the fastening on the conductive film.

23. The method as recited in claim 14, wherein alignment marks are introduced into the conductive film before the fastening of the at least one electronic component on the conductive film.

24. The method as recited in claim 15, wherein alignment marks are introduced into the conductive film before the fastening of the at least one electronic component on the conductive film.

25. The method as recited in claim 16, wherein alignment marks are introduced into the conductive film before the fastening of the at least one electronic component on the conductive film.

26. The method as recited in claim 17, wherein holes are introduced into the conductive film at the positions at which the at least one additional electronic component is to be electrically contacted with the conductive film.

27. The method as recited in claim 26, wherein the holes for contacting the conductive film with the at least one additional electronic component are metal plated.

28. The method as recited in claim 14, wherein additional layers, which contain printed conductor structures, are applied to the conductive film which is structured.

29. The method as recited in claim 14, wherein the at least one electronic component is contacted with a heat sink on the side facing away from the conductive film before the lamination, so that the heat sink is integrated in the circuit board after the lamination onto the circuit board carrier.

30. An electronic assembly, comprising: at least one electronic component, which is connected to a printed conductor structure on a circuit board, the at least one electronic component being embedded in a circuit board carrier and the printed conductor structure being positioned on the surface of the circuit board, wherein contacting of the component with the circuit board structure is performed by contacting points attached to the component.

31. The electronic assembly as recited in claim 30, wherein the contacting points are solder bumps or stud bumps.

32. The electronic assembly as recited in claim 30, wherein the printed conductor structure is implemented in multiple layers.
